(19) United States
(12) Patent Application Publication
(10) Pub. No.: US 2013/0141137 A1
(43) Pub. Date: Jun. 6, 2013

(54) Stacked Physically Uncloneable Function Sense and Respond Module

(71) Applicants: Christian Krutzik, Costa Mesa, CA (US); Stewart Clark, Newport Beach, CA (US); W. Eric Boyd, Long Beach, CA (US)

(72) Inventors: Christian Krutzik, Costa Mesa, CA (US); Stewart Clark, Newport Beach, CA (US); W. Eric Boyd, Long Beach, CA (US)

(73) Assignee: ISC8 Inc., Costa Mesa, CA (US)

(21) Appl. No.: 13/486,500

(22) Filed: Jun. 1, 2012

Related U.S. Application Data
(60) Provisional application No. 61/492,156, filed on Jun. 1, 2011.

(51) Int. Cl. H03K 19/173

(52) U.S. Cl. CPC H03K 19/173
USPC 326/8

(57) ABSTRACT

A physically uncloneable function (PUF) sense and response module fabricated from a stack of integrated circuit chip layers. At least one of the PUF chips in the stack has a unique identifier resulting from random effects of fabrication processes. The PUF chip generates the fingerprint at power-on resulting that in turn is used to generate a private key. The private key generates a public key used to communicate with the outside world. The encrypted data from the outside world is decrypted with the private key. The public key is stored for comparison with pubic keys generated at subsequent power-up operations. If the key changes, tampering is indicated and a predetermined tamper response event is generated such as the erasing of the contents of a memory.

### REFERENCE TO RELATED APPLICATIONS

This application is related to U.S. Provisional Patent Application No. 61/492,156 entitled “Physically Uncloneable Sense and Response Module”, filed Jun. 1, 2011 which is incorporated herein by reference and to which priority is claimed pursuant to 35 U.S.C. 119.

### STATEMENT REGARDING FEDERALLY SPONSORED RESEARCH AND DEVELOPMENT

N/A

### BACKGROUND OF THE INVENTION

1. Field of the Invention

The invention relates generally to the field of electronic circuits and modules. More specifically, the invention relates to a physically uncloneable function (“PUF”) sense and respond circuit and module to provide secure private encryption key generation and storage having one or more tamper-resistant circuit functions.

2. Description of the Related Art

In general, physically uncloneable function or “PUF” electronic devices rely on random and specific physical characteristics of a device to create a random, stable identifier or “fingerprint” of that device.

The first such devices were film-based devices introduced by Pappu et al. in 2002. They used laser light scattered off bubble-filled transparent epoxy films to generate random interference patterns.

Since then, silicon PUFs (SPUFs) have been introduced that take advantage of slight, random differences in signal delays of internal signal lines which are designed using symmetrical path race conditions, or that take advantage of the doping or other mismatch between gates in memory structures, such as SRAM cells, cross-coupled NOR gates or cross-coupled latches or butterfly circuits. These slight variations arise from random, uncontrollable variations in semiconductor processes used in the fabrication of the integrated circuit and vary from device-to-device; resulting in a unique device fingerprint identifier for each.

Like a biometric fingerprint, a device fingerprint is not always perfectly identical but is sufficiently reproducible to be used to uniquely identify one device fingerprint from that of another. The same type of fingerprint post-processing employed with biometric data can be used to establish an initial private key from a particular electronic device fingerprint and subsequently recover that same key even in the presence of noise.

### SUMMARY OF THE INVENTION

The “no electrical power” aspect of the invention provides secure private key generation and storage and tamper resistance in the event an unauthorized user or an adversary attempts to probe or discover data in the PUF module of the invention even where there is no electrical power available for detection or erasure. The module further inhibits or prevents discovery of sensitive information when system power is reapplied to boot-up stored encrypted data.

In a preferred embodiment of the invention, a small three-dimensional microelectronic module is provided that comprises a stacked and layered physically uncloneable function that stores random yet stable data in way that cannot be cloned or determined by modeling or probing.

In addition, a fusible link means or fuse element may be provided that prevents module operation by an adversary. The fuse element may be configured to be selectively activated (i.e., “opened”) upon a predetermined event or time by an authorized user as part of mission operation step or configured to open in the event of attempt to probe the module whereby the module generates a predetermined tamper response such as zeroization or rewriting of the contents of a memory.

The module generates, extracts and stores a private encryption key from the fingerprint data on the PUF device which in turn is used to generate a public key made available outside the module. The public key in turn is used at a secure location to store an encrypted boot program that can be decrypted internal to the module only by use of the private key. The boot program may be stored either openly in the system or, for enhanced security, within an anti-tamper structure encasing the module.

In normal module operation, when power is applied, the module boot-ups a decrypted secure program using the private key if the fuse element has not been activated or blown. If the fuse element has been opened or if the data with which the private key is restored has been altered, the module is automatically rendered inoperable and the program and operation in memory is secured.

The PUF module may be comprised of one or more SRAM IC chips where a positive feedback cross-coupled element used for data storage comes up in a stable repeatable bit pattern that is different from one chip to another due to uncontrollable small fabrication process variations. These variations result in a “signature pattern” at power-up due to, for instance, slight differences in threshold voltages. The threshold differences are magnified in sub-threshold operation which is where most low-power circuits operate.

By placing a modifier film layer having a random distribution of bias-carrying voltages or a film of high dielectric particles which integrate a pattern variation on the modifier layer in addition to the original pattern, a truly random and secure pattern is generated which is destroyed if the distance or alignment of the modifier is disturbed by tampering.

If the private key is used to boot up a processor on the module in a secure mode and the power is only available on predetermined protected nodes, the power can be interrupted and, as long as the private key is destroyed, the processor is disabled. If the memory has been encrypted, it does not need to be destroyed but may be configured to be at the same time.

The module's SRAM arrays may be modified by the modifier layer based on the fact that when a static RAM powers on, individual bits initially come up in a random pattern of ones and zeros based on mismatches in the cross-coupled CMOS inverters in the six-transistor cells comprising the SRAM. These mismatches are primarily due to threshold variations due to fluctuations in the dopant levels across the chip. These fluctuations become more pronounced as cell sizes decrease. Variations in lithography or common mode noise such as supply variations are minimal; however other noise sources can affect some of the cells, especially those that have neutral skew (neither skewed to “zero” or “one” state). A neutrally-skewed cell does not necessarily have transistors that are perfectly matched but instead the transistors have some unknowable combination of variations that are approximately offsetting when powered up and may change over temperature or voltage. Accordingly, the SRAM fingerprint is a fuzzy identifier of a particular chip in the same manner as a literal fingerprint is a fuzzy identifier of a particular human.

A purpose is to provide a chip plus modifier layer that is necessary in forming the physical uncloneable function (PUF) or fingerprint that generates a private key. This layer covers and protects access to a fuse element and if the layer is tampered with, the PUF (fingerprint) is changed so it no longer generates the original private key. The fuse function disables the operation of the PUF circuits so that the only way to bypass the fuse results in modification (loss) of the original fingerprint.

The PUF chip electronic circuits may be provided as cross coupled bi-stable circuits such as static RAM circuits that are very sensitive to unavoidable threshold variation shifts that are impossible to control accurately, especially very small geometry circuits. This desirably results in a unique pattern or fingerprint at power-on that distinguishes one chip from another.

The modifier layer includes randomly distributed small particles that further modify the fingerprint to another unique fingerprint. Examples could be the inclusion of high dielectric particles in combination with a bias film that imposes a pattern of bias variations across the gates on the chip or even light modification element (reflection or absorption) that changes gate voltages with photo-effects.

These and various additional aspects, embodiments and advantages of the present invention will become immediately apparent to those of ordinary skill in the art upon review of the Detailed Description and any claims to follow.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE DRAWINGS

FIG. 1 depicts a preferred embodiment of the physically uncloneable function sense and respond module of the invention in a stacked, multi-layer configuration.

FIG. 2 depicts a FET nano-fuse of the invention.

The invention and its various embodiments can be better understood by turning to the following description of the preferred embodiment which is presented as an illustrated example of the invention in any subsequent claims in any application claiming priority to this application.

It is expressly understood that the invention as defined by such claims may be broader than the illustrated embodiments described below.

### DETAILED DESCRIPTION OF THE PREFERRED EMBODIMENTS

There is a need for secure storage of private encryption key data in electronic devices that may be subject to reverse engineering such as in military electronics that can be examined by an adversary. Such devices can be provided by using a unique fingerprint identifier for the device coupled with random number generation using neutral-skewed cells in memory cells that randomly power up in a one or zero state due to variations in noise or other factors.

The physical fingerprint in an SRAM chip PUF embodiment of the invention is the power-up state generated by the memory cells of the layers and serves as a fuzzy identifier for each of the layers.

Certain of the memory cells are neutrally-skewed and power-up in different digital states due to random noise in a series of power-up operations. Comparing this effect to human fingerprinting, a pattern from a single trial can be called a latent fingerprint. A known fingerprint is an intentional estimation of the state most likely to be generated at power-up by averaging multiple power-up trials. If the fingerprint is large, identification is made possible by the module executing and algorithm that identifies the similarity between the known fingerprint of the SRAM chip in a layer and all possible latent fingerprints from the layer as opposed to the dissimilarity between fingerprints from different SRAM chips in a layer.

Such devices are discussed for instance, in “Power-up SRAM State as an Identifier Fingerprint and Source of True Random Numbers”, Holcomb et al., IEEE Transactions on Computers, Vol. 57, No. 11, November 2008, and “Physically Uncloneable Functions: A Study on the State of the Art and Future Research Directions”, Maes et al., Towards Hardware-Intrinsic Security (Springer), 2010, the entirety of each of which is incorporated herein by reference.

The device of the invention is a physically uncloneable function sense and respond module. In a preferred embodiment, the device comprises an SRAM stacked module which may be integrated with layers comprising one or more anti-tamper functions that provide further advantage when coupled with the above random processing and noise characteristics.

The device is not limited to the use of SRAM IC chips and may comprise, for instance, butterfly network ASICs or any other electronic circuitry that power-on with a random but repeatable bit pattern that can be read out by suitable electronic circuitry

The module is a no-power, private key storage device that assures the internally stored private key cannot be obtained either by physical reverse engineering or by an electronic probing operation. The device is configured to prevent unauthorized power-up with permanent data destruction measures and protects key data from physical, optical, radiation, electromagnetic, or sonic interrogation. Key data is contained in and derived from minute uncontrollable process-induced threshold or photolithographic variations or both occurring as the result of the fabrication of silicon circuits and which variations may be further modified by a special film or modifier layer.

Attempts to dismantle the PUF module of the invention result in permanent destruction of the encrypted information in the module comprising, in one embodiment, a combination of two or more stacked and complementary PUF layers and at least one modifier layer.

When extracted with accompanying “helper data”, the random fingerprints reproduce the private key each time power is applied to the module. The private key is used to decrypt the secure boot program that has been encrypted with a public key.

An embedded fuse element may be provided to prevent subsequent reboots once the fuse is activated, i.e., blown. The fuse element is disposed within the device structure such that it cannot be physically accessed without destroying the private key that is stored in a physically uncloneable function. In this manner, even if an adversary is successful in gaining access to a power line on the inboard side of the fuse, tamper attempts will be unsuccessful because the key itself will have been destroyed such that the module can no longer be booted in secure mode.

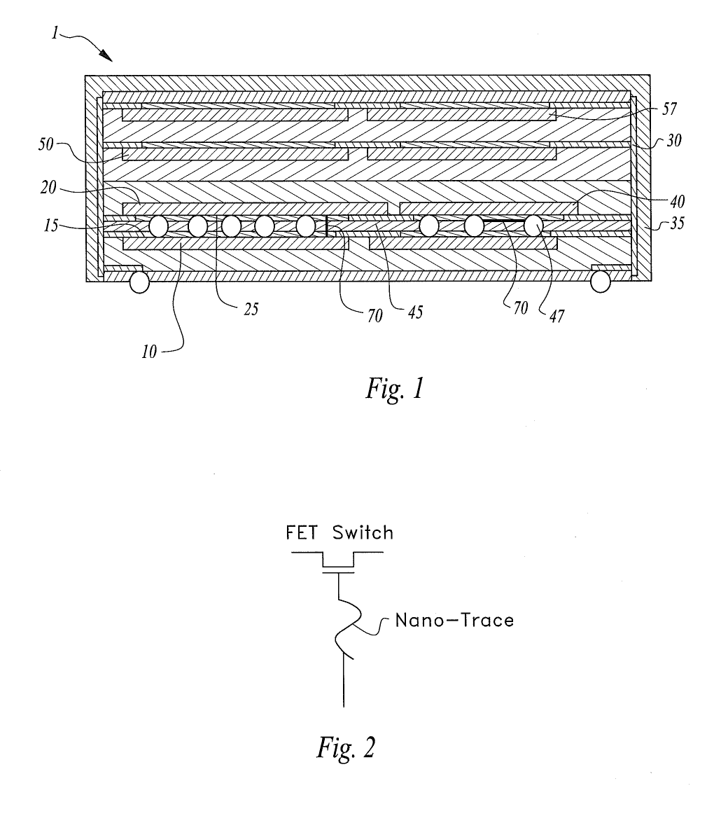

Turning now to the figures, a preferred embodiment of the physically uncloneable function sense and respond module 1 is shown in FIG. 1.

Module 1 may be used for the generation and secure storage of a private encryption key and may comprise a first physically uncloneable function IC layer 10 having a first active surface 15 comprising at least one random semiconductor fabrication process-induced variation to define a first fingerprint value. First layer 10 may comprise an SRAM IC chip having one or more neutral-skewed cells defined on the first active surface.

A second physically uncloneable function IC layer 20 is provide having a second active surface 25 comprising at least one random semiconductor fabrication process-induced variation to define a second fingerprint value. Second layer 20 may comprise an SRAM IC chip having one or more neutral-skewed cells defined on the second active surface.

The first and second layers are bonded together to form a three-dimensional microelectronic module 1 wherein at least one I/O of the first IC layer is electrically coupled to at least one I/O of the second IC layer such as by side-bussing or T-connect metallization structures 30 defined on a lateral surface of the module.

Module 1 may be provided with an anti-tamper wrapper or enclosure 35 such as disclosed in U.S Pub. No 2011/0031982, “Tamper-Resistant Electronic Circuit and Module Incorporating Conductive Nano-Structures”, now pending and assigned to Irvine Sensors Corp., assignee of the instant application and the contents of which is fully incorporated herein by reference to provide a predetermined tamper response in the event the wrapper is damage or breached.

Circuit means 40 is provided for algorithm execution and storing an extracted private encryption key using the first and second fingerprint values and using at least one neutral-skewed memory cell value derived from at least one of the first or second layers.

Module 1 further comprises a modifier layer 45 disposed between first layer 10 and second layer 20.

In one embodiment, one or more nodes 47 in one or more of the SRAM cells are exposed such that an external capacitance/charge or other external physical factor affects the initial power-up state of the cell. For example, a modifier layer may have a randomly-dispersed dielectric constant material in it so that when disposed between the first and second layers, it cannot be recreated with the exact material composition, distance, or orientation with respect to each exposed node. In such a case, prying the stack apart will destroy the modifier layer as it cannot be reassembled.

It is not necessary the nodes be physically exposed though they may be (as in case of nano-reroute). It is sufficient to bring out the nodes to larger surface area “pads” on the respective layer die such that they may easily be electrically coupled.

Similarly, inductive elements may be incorporated into the modifier layer such that modifier layer creates a back-EMF (impedance) which influences the power-up state of one or more neutral-skewed cells in the layers.

A yet further alternative embodiment comprises the use of internally and randomly provided LEDs as modifiers in the modifier layer such that specific wavelength, drive, dispersion characteristics of LEDs affects the power-up state of one or more neutral-skewed SRAM cells on the layers.

Further, a modifier layer may be provided that comprises one or more nano-reroutes between them to connect exposed nodes so that the varying resistance, capacitance, inductance or other predetermined physical characteristic in the surrounding modifier layer material would influence the neutral-skew SRAM cell state at power up. Again, such a structure would be destroyed with a physical tamper event.

Module 1 may be provided wherein the semiconductor process-induced variation includes a threshold-induced variation resulting from a dopant fluctuation between a plurality of the SRAM transistor cells in at least one of the first or second layers.

Module 1 may be provided wherein the semiconductor process-induced variation includes a photolithography-induced variation between a plurality of SRAM transistor cells in at least one of the first or second layers.

In a yet further alternative embodiment, module 1 further comprises a secure supervisor IC layer electrically coupled to at least one of the first or second layers as is discussed more fully below.

Preferably, module 1 is configured so that the first and second active surfaces are bonded face-to-face to a shared modifier layer.

The modifier layer may comprise a modifier element that changes state when exposed to a predetermined range of the audio spectrum. The modifier layer may comprise a modifier element that changes state when exposed to a predetermined range of the ultrasonic spectrum. The modifier layer may comprise a modifier element that changes state in the presence of a predetermined range of the electromagnetic spectrum. The modifier layer may comprise a modifier element that changes state in the presence of a focused ion beam. The modifier layer may comprise modifier element that changes state when exposed to mechanical vibration.

Module 1 may further comprise circuit means for reconfiguring at least one I/O in the module as a result of a predetermined tamper event such as by use of a field programmable gate array (FPGA), complex programmable logic device (CPLD), microprocessor or equivalent electronic circuit element 57 in a layer in the module 1.

Module 1 may comprise fuse element means 70 configured to disable an electronic function in the module as a result of a predetermined tamper event.

Fuse element means 70 may be configured to be activated, open or “blown” by means of the output current of an embedded piezoelectric device in the module 1 that is activated by vibration or twisting of the module 1.

Fuse means 70 may be configured to be blown by the output current of an embedded photodiode in the module resulting from electromagnetic radiation input.

As depicted in FIG. 2, fuse means 70 may comprise at least one nano-trace having a trace width of less than about 200 nanometers.

The modifier layer may be integrated between the first and second layers such that it also influences the fingerprint only one or both of the layers.

All layers are preferably stacked into a single module with I/O provided from only one of the layers. This eliminates the ability to perform any direct external probing of the inaccessible without destruction of the layer exposed for to probing.

The first and second layers are preferably disposed in the module to have their respective active IC die surfaces (i.e., die surfaces having electronic circuitry defined thereon) “face-to-face” making it physically challenging to separate the respective layers as well as requiring the destruction of one layer to access or prove the other.

For example, if either layer of the illustrated module is removed (such as by grinding, etching, polishing, etc.) to access the respective opposing layer, the private key information is destroyed because one half of the fingerprint has been destroyed in the removal of the layer.

Since the module of the invention is inherently uncloneable, there is no possibility to recover the key from further physical or electronic analysis, nor can it ever be recovered by analyzing other modules.

In addition, particles affected by X-rays, radiation, or other forms of energy may be embedded in the modifier layer. Structures may also be embedded that change with electromagnetic radiation or change from sonic energy, such as a piezoelectric device or photodiode internal to the stack.

A beneficial feature of the module of the invention is that in a non-electrical environment it does not store data in the conventional sense as in an EEPROM or flash memory device, which devices undesirably retain readable data in memory even when unpowered.

Since the private key data or fingerprint that comprises the private key is effectively generated and stored in the form of minute semiconductor process variations that cannot be reproduced, module 1 must be powered on to “activate” or “read” these process variations and then read out the private key data. In a sense, the process of powering up of module 1 recreates the key from “scratch” each time (i.e., it is not conventionally stored) and is why it cannot be accessed while unpowered.

Generating a private key from the fingerprint identifier pattern requires an initial “enrollment” process whereby a private key is established in conjunction with public “helper data”. During subsequent reconstruction phases, this helper data is used to re-establish the exact private key in the presence of noisy data. It is this process that places a requirement for extra memory bits. As an example, 4-5 Kbits may be required to reliably reconstruct a 128-bit key.

To power one of the layers (and to access IO), small traces may be rerouted internally on the module in multiple locations that also serve as fuse elements 70 such as a nano-fuse element of FIG. 2.

Using known anti-tamper security techniques, a failed power-on authorization may be configured to send a signal in the form of a predetermined tamper response to the PUF module to irreversibly break the power line by opening or activating the fuse element. This is a fast process and is not interruptible by an adversary.

Integrated capacitors or an internal battery may also be provided and configured to function as a mini-UPS (uninterruptable power supply) in module 1. Although the fingerprint data can only be accessed by applying power, this provides the ability to open internal fuse elements when power is unavailable.

Secure supervisor chips may be provided in module 1 to monitor power and verify abnormal power-up conditions. Since the embedded power connections and blown fuses are deeply integrated between the layers, any attempts to access the area mechanically will result in destruction of the fingerprint.

A further benefit of the use of a stack of integrated circuit chips is the inherent difficulty an unauthorized user will have in attempting to tamper with, electrically probe or reverse engineer the individual circuit elements in the stack, i.e., the difficulty in identifying the nature, function and I/O locations of the chips in the stack and the difficulty presented in physically reverse engineering or tampering with the device without destroying it such as by grinding, FIB, probing, X-ray, etching or other tampering or reverse engineering methods.

Integrated circuit die stacking was pioneered by ISC8, Inc. (formally known as Irvine Sensors Corporation), assignee of the instant application, as is disclosed for instance in U.S. Pat. No. 5,581,498, “Stack of IC Chips in Lieu of Single IC Chip” and other die stacking patents issued and assigned to Irvine Sensors Corp.

Means for detecting a tamper event resulting from an attempt to physically breach or probe the memory contents of the device 1 may further comprise the use of the nano-trace sensing structures or other tamper-sensing means such are disclosed in U.S. Pub. No. 2011/0227603, “Secure Anti-Tamper Integrated Security Device Comprising Nano-Structures”, now pending, and U.S. Pub. No. 2011/0031982, “Tamper-Resistant Electronic Circuit and Module Incorporating Conductive Nano-Structures”, now pending and assigned to Irvine Sensors Corp., assignee of the instant application and the contents of each of which is fully incorporated herein by reference.

The Maxim DS3655 Secure Supervisor from Maxim Integrated Products, Inc. is well-suited for use as an element of module 1 and provides tamper-detection comparator inputs that interface with and provide continuous, low-power monitoring of resistive anti-tamper resistive meshes, external sensors, and digital interlocks.

The Maxim DS3655 device provides circuitry that monitors primary power and, in the event of failure, an external or embedded storage capacitor or battery power source is switched in to keep the device and external circuitry active. The DS3655 also monitors battery voltage and initiates a tamper response such as erasure of the contents of the memory elements when the battery voltage becomes abnormal or there is a predetermined temperate limit or rate of change that is exceeded.

Module 1 may further comprise an embedded or external battery or capacitor element such as an electric double layer capacitor known as a “super capacitor” functioning as a standby power source used to zeroize the contents of the device memory elements or stored encryption keys in the anti-tamper element or other stored contents of module 1 in the event a tamper event is detected to keep volatile memory, RTC circuitry and tamper-detection and zeroization circuitry active and functioning during or after a tamper attempt.

Module 1 of the invention may comprise the use of one or more electrically conductive nano-structures defined on one or more surfaces of a microelectronic circuit such as an integrated circuit die, microelectronic circuit package (such as a TSOP, BGA or other prepackaged IC formats), a stacked microelectronic circuit package or on the surface of one or more layers in a stack of layers containing one or more ICs.

In one embodiment of the invention, the electrically conductive nano-structure acts as a sensor for the detection of a predetermined variance in a predetermined electrical characteristic of the electrically conductive nano-structure. The electrically conductive nano-structure is in electrical connection with a monitoring circuit and together the elements act as an electronic “trip wire” to detect unauthorized tampering with the device or module. Such a monitoring circuit may include an internal or external power source (e.g., an in-circuit or in/module battery) in combination with a related “zeroization” circuit within the chip or package to erase the contents of a memory when the electrically conductive nano-structure is breached of senses a predetermined change in a predetermined electrical characteristic.

In yet a further embodiment of the invention, one or more electrically conductive nano-structures are used to interconnect and reroute one or more electrical connections between one or more ICs (or act as dummy leads, connections and/or conductive through-hole vias) to create an “invisible” set of electrical connections on or in the chip or stack, i.e., a set of electrical connections that cannot be easily observed by standard test or reverse engineering means such as by X-ray or conventional microscope.

In an alternative embodiment, various environmental detectors in a non-electrical power environment are incorporated to couple them with nano-fuse traces embedded between the first and second layers. Similar to the power protection circuitry, the nano-fuses are configured to blow and prevent reading out the layers. The nature of the module 1 protects the fuse element 60 from being reconnected; to reset the fuse would require destroying one of the layers from which the private key is derived.

The following claims are intended not only to cover the specific embodiments disclosed, but also to cover the inventive concepts explained herein with the maximum breadth and comprehensiveness permitted by the prior art.

The words used in this specification to describe the invention and its various embodiments are to be understood not only in the sense of their commonly defined meanings, but to include by special definition in this specification, structure, material or acts beyond the scope of the commonly defined meanings. Thus, if an element can be understood in the context of this specification as including more than one meaning, then its use must be understood as being generic to all possible meanings supported by the specification and by the word itself.

The definitions of the words or elements are defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements or that a single element may be substituted for two or more elements.

Insubstantial changes from the subject matter as viewed by a person with ordinary skill in the art, now known or later devised, are expressly contemplated as being equivalent. Therefore, obvious substitutions now or later known to one with ordinary skill in the art are defined to be within the scope of the defined elements.

The inventions are thus to be understood to include what is specifically illustrated and described above, what is conceptually equivalent, what can be obviously substituted and also what essentially incorporates the fundamental idea of the invention.

Although elements may be described above as acting in certain combinations, it is to be expressly understood that one or more elements from a combination can, in some cases be excised from the combination and that the combination may be directed to a sub-combination or variation of a subcombination.

We claim:

1. A microelectronic module for the generation and secure storage of a private encryption key comprising:
a first physically uncloneable function IC layer having a first active surface comprising at least one random semiconductor fabrication process-induced variation between a plurality of neutral-skewed cells to define a first fingerprint value,
a second physically uncloneable function IC layer having a second active surface comprising at least one random semiconductor fabrication process-induced variation between a plurality of neutral-skewed cells to define a second fingerprint value,
the first and second layers bonded to form a three-dimensional microelectronic module wherein at least one I/O of the first IC layer is electrically coupled to at least on I/O of the second IC layer, and,
circuit means for generating and storing a private encryption key using the first and second fingerprint values and using at least one neutral-skewed memory cell value derived from at least one of the first or second layers.

2. The module of claim 1 further comprising a modifier layer having at least one predetermined and randomly dispersed element disposed between the first layer and the second layer whereby the neutral-skewed memory cell value is influenced as the result of the element when the module is powered up.

3. The module of claim 2 wherein the semiconductor process-induced variation is a threshold-induced variation resulting from a dopant fluctuation between a plurality of transistor cells in at least one of the first or second layers.

4. The module of claim 2 wherein the semiconductor process-induced variation is a photolithography-induced variation in at least one of the first or second layers.

5. The module of claim 2 further comprising a secure supervisor IC layer.

6. The module of claim 2 wherein the first and second active surfaces are bonded to a shared modifier layer.

7. The module of claim 2 wherein at least one of the first and second IC layers comprises an SRAM IC chip comprising at least one neutral-skewed cell.

8. The module of claim 2 wherein the modifier layer comprises a modifier element that changes state when exposed to a predetermined range of the audio spectrum.

9. The module of claim 2 wherein the modifier layer comprises a modifier element that changes state when exposed to a predetermined range of the ultrasonic spectrum.

10. The module of claim 2 wherein the modifier layer comprises a modifier element that changes state in the presence of a predetermined range of the electromagnetic spectrum.

11. The module of claim 2 wherein the modifier layer comprises a modifier element that changes state in the presence of a focused ion beam.

12. The module of claim 2 wherein the modifier layer comprises modifier element that changes state when exposed to mechanical vibration.

13. The module of claim 2 further comprising circuit means for reconfiguring at least one I/O in the module as a result of a predetermined tamper event.

14. The module of claim 2 further comprising fuse means configured to disable an electronic function in the module as a result of a predetermined tamper event.

15. The module of claim 14 wherein the fuse means is blown by the output current of an embedded piezoelectric device in the module.

16. The module of claim 14 wherein the fuse means is blown by the output current of an embedded photodiode in the module.

17. The module of claim 14 wherein the fuse means comprises at least one nano-trace having a trace width of less than about 200 nanometers.

18. The module of claim 17 wherein the nano-trace is disposed between and electrically coupled to the first and second layers.
